(19) United States
(12) Patent Application Publication
(10) Pub. No.: US 2006/0291180 A1
(43) Pub. Date: Dec. 28, 2006

(54) PCI mezzanine card

(75) Inventors: Chi-Wei Yang, Taipei (TW); Sheng-Yuan Tsai, Taipei (TW)

Correspondence Address: APEX JURIS, PLLC;TRACY M HEIMS, LAKE CITY CENTER, SUITE 410, 12360 LAKE CITY WAY NORTHEAST, SEATTLE, WA, 98125, US

(73) Assignee: Inventec Corporation, Taipei (TW)

(21) Appl. No.: 11/165,631

(22) Filed: Jun. 23, 2005

(51) Int. Cl. H05K 1/14

(52) U.S. Cl. 361/785; 361/788; 361/803

(57) ABSTRACT

Disclosed is a PCI mezzanine card (PMC) with pin-grid-array (PGA) which can be applied onto a two or more central processing unit (CPU) socket equipped mother board When one of the CPU sockets is not installed with a CPU, the PMC communicates with the mother board through the CPU socket with its PGA interface. An IC package mounted on the PMC can communicate with the mother board through the PMC.

### BACKGROUND OF THE INVENTION

1. Field of Invention

The present invention relates to a Protocol-control-information Mezzanine Card (PMC), and particularly to a PMC being electrically coupling to a central processing unit (CPU) socket on a computer mother board. The Protocol-Control-Information is further abbreviated to be PCI.

2. Description of the Related Art

A PCI mezzanine card (PMC) module is used for I/O expansion on a computer mother board and a PCI bus serves as an interface between a card and a PMC module. The PCI bus is adopted for this purpose since most of I/O functions can be realized through the PCI interface. For example, a display card in a computer is such PMC with a displaying function, which may be inserted onto a connector connected to the PCI bus of the computer mother board.

When the PMC is used as an I/O interface, the mother board has to be limited in altitude at a specific area (the PMC typically has a specific width and a specific altitude with respect to the mother board) and the area has to be installed with connectors so that the PMC may be connected to the PCI bus on the computer mother board. However, the connectors require an area to be taken up on the computer mother board. Accordingly, when such arrangement is used with a two or more CPU sockets equipped mother board (e.g. a server-level mother board), layout of the connectors and the other components on the mother board is unavoidably limited.

An example of the two CPUs equipped mother board is shown in FIG. 1, which is a server-level mother board having two AMD CPUs installed thereon. As shown, two CPU sockets 110, 120, a memory slot 130 and connectors 140 (PMC sockets) are installed on the mother board 100.

Since the two CPU sockets 110, 120 exist on the mother board 100, each of the connectors 140 may have a relatively limited area for layout thereon (only four connectors 140 are permitted to be installed in FIG. 1). When additional PMCs are to be added onto the mother board 100, it would be impossible to accommodate these additional PMCs for the mother board since number of the connectors 140 has been limited owing to the limited layout area.

When the connectors on the mother board are all inserted with the PMCs, it is impossible to locate an area for mounting additional connectors in the limited layout area when additional PMCs are to be introduced onto the computer mother board. In this regard, the mother board does not provide a sufficient flexibility in its PMC layout.

On the other hand, the PMC providers may only provide PMCs compatible with the connectors provided by the mother board so that the PMCs may be connected to the PCI bus on the mother board and function normally. Accordingly, the PMCs to be used may not be selected in their specifications with respect to a specific computer mother board.

In light of the above disadvantage, there is a need to provide a PMC which is capable to communicate with the PCI bus without the intermediate of the connectors so that the mother board may provide a diversity of PMC I/O interfaces and the PMC can still communicate with the PCI bus by using an alternative interface.

### SUMMARY OF THE INVENTION

It is, therefore, an object of the present invention to provide a PCI mezzanine card (PMC) with a greater selectivity and a PMC I/O interface with a greater diversity on a computer mother board. To achieve the above object, the PMC according to the present invention comprises a main frame, a slot, pin-grid-array (PGA) and wire layouts. The main frame is a thin board and has a top side and a bottom side. The slot has a plurality of contact points each electrically coupling to one of said pin. The slot is located on either the top or the bottom side of the main frame 215. The contact points of the slot are electrically coupling to the IC packages that the IC package can be mounted on the slot. The PGA are provided corresponding to holes of a central processing unit (CPU) socket on the computer mother board and may be inserted into the holes of the socket. The wire layouts are mainly located on the top side of the main frame and connected electrically to the socket and PGA on the main frame so that the IC package mounted on the main frame may be electrically coupling to the CPU socket through the PGA.

The PMC of the invention is mainly used on a two or more CPU sockets equipped mother board. When one of the CPU sockets is not installed with a CPU, the PMC has an interface of PGA which is designed to physically and electrically match with the CPU socket.

To enable one skilled in the art to further understand the objects, features and functions of the present invention, the more detailed description of the preferred embodiments of the present invention is provided below in connection with the accompanying drawings and through which the present invention can be implemented and practiced.

### BRIEF DESCRIPTION OF THE DRAWINGS

The invention will become more fully understood from the detailed description given hereinbelow illustration only, and thus are not limitative of the present invention, and wherein:

FIG. 1 is a schematic diagram showing a two central processing units (CPUs) equipped mother board; and

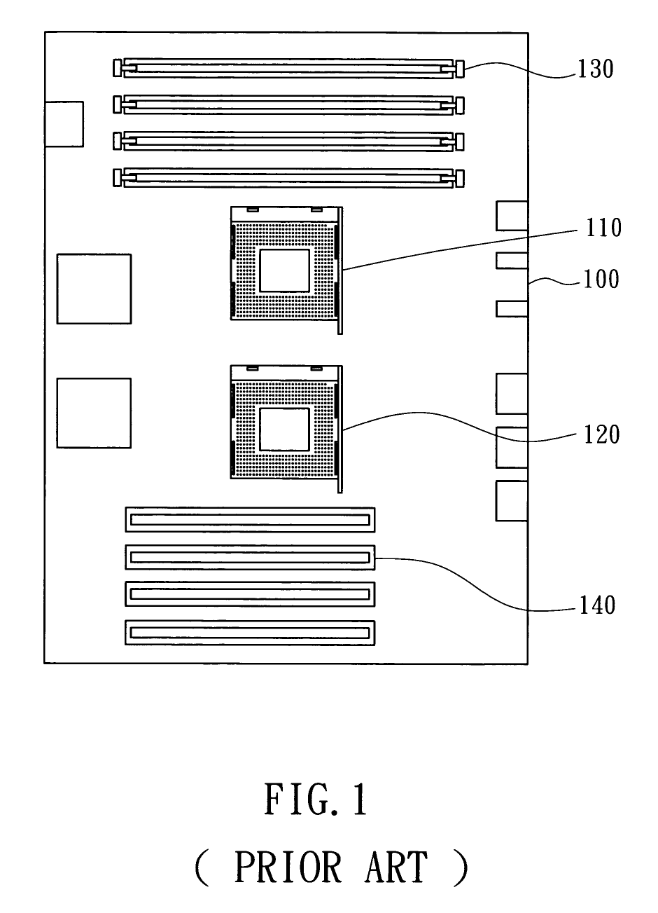

FIG. 2 is a schematic diagram showing a protocol control information (PCI) mezzanine card (PMC) according to a preferred embodiment of the present invention.

### DETAILED DESCRIPTION OF THE INVENTION

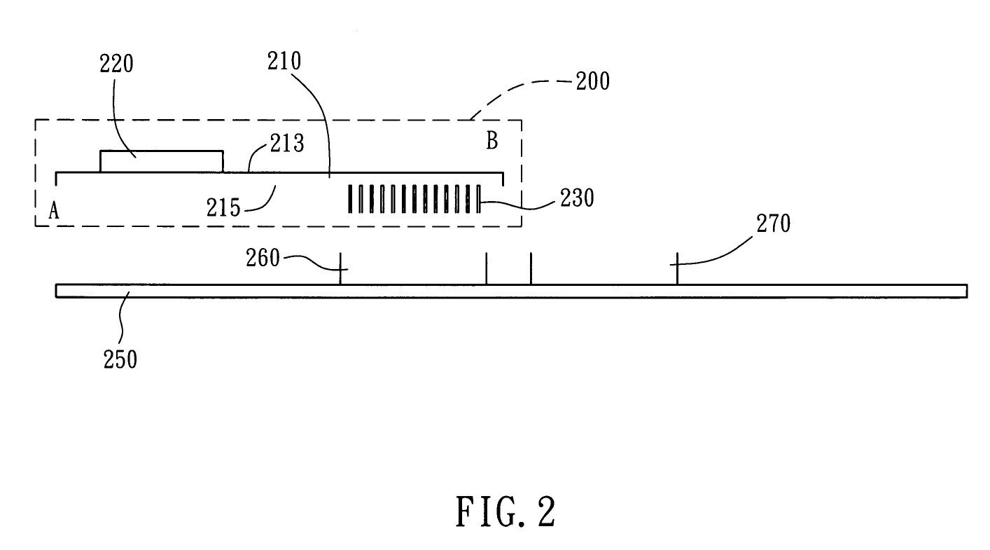

Referring to FIG. 2, a PCI (protocol control information) mezzanine card (PMC) of the present invention is schematically depicted therein. As shown, the PMC 200 comprises a main frame 210, a slot 220 and PGA 230.

The main frame 210 has a top side 213 and a bottom side 215. On the main frame 210, the slot 220 is disposed on the top side 213 near one end A and the PGA 230 are disposed on the bottom side 215 near the other end B. The slot 220 can be inserted with an IC package (not shown). The PGA 230 is designed electrically coupling to the socket 260 so that the PGA 230 can insert into the CPU socket 260.

Since the objects of the present invention are to provide the PMC with a greater selectivity with respect to a PCI bus on a computer mother board and provide a PMC I/O interface with a greater diversity, the PMC of the invention is more suitable to be used in a two or more CPU sockets equipped computer mother board. FIG. 2 depicts such a mother board, where two CPU sockets 260, 270 are installed on the mother board 250. When the CPU socket 260 is not installed with a CPU (not shown), the PMC 200 may be inserted into the CPU socket 260 through its PGA 230. The wire layouts on the top side 213 are circuit design electrically coupling between the slot 220 and the PGA 230. As such, an IC package can be mounted on the slot 220 and therefore electrically coupling to the CPU socket 260.

That is, when one of the CPU sockets 260, 270 of the mother board 250 is not installed with a CPU, the CPU socket 260 can be used as an interface to the PMC 200. As such, the IC package mounted on the PMC 200 may transmit/receive signals to and from the CPU socket 260 and the mother board 250. Through such a connection arrangement, an additional PMC I/O interface can be added on the mother board 250.

The present invention possesses the following advantages: a) Since the PMC 200 is on the top of the CPU socket 260 and electrically coupling to the CPU socket 260, the top area of the CPU socket 260 can be fully utilized. b) The PMC 200 with PGA 230 I/O interface to communicate with the CPU socket 260 provides design diversity and selectivity as compared to the conventional PMC I/O interface. c) The PMC 200 as described in this invention can be applied onto a two or more CPU sockets equipped mother board and particularly suitable in the case that one of the CPU sockets is not installed with a CPU since the CPU socket 260 can be connected with the PMC 200 having an I/O interface of PGA 230. At the same time, the CPU socket 260 not installed with a CPU can be sufficiently utilized. d) With the PMC I/O interface of PGA 230 electrically compatible to the CPU socket 260, it is possible to have different cards electrically coupling to the mother board 250 and thus many business chances may be created.

In conclusion, the present invention discloses a PMC 200 which can be electrically coupling to a CPU socket 260 on a computer mother board through PGA interface. The PMC 200 of the invention can be used on a two or more CPU sockets equipped computer mother board and applied on one of the CPU sockets which is not installed with a CPU. With this PGA 230 I/O interface, an IC package installed on the PMC 200 can function normally. Accordingly, the PMC 200 with PGA design of the invention provides a diversity of design choices and lends itself to more business chances.

While the preferred embodiments of the invention have been described, it will be apparent to those skilled in the art that various modifications may be made without departing from the spirit of the present invention. Such modifications are all within the scope of the present invention.

1. A protocol control information mezzanine card (PMC), comprising:
a main frame being a thin board and having a top side and a bottom side;
a slot located on said main frame for electrically mounting of an IC package;
a pin-grid-array (PGA) for communicating between said main frame and a CPU socket; and
wiring on said main frame for electrically coupling between said slot and said pin-grid-array.

2. The PMC as recited in claim 1, wherein said PMC is applied onto a two CPU sockets equipped computer mother board.

3. The PMC as recited in claim 2, wherein said slot has a plurality of contact points each electrically coupling to one of said PGA.

4. The PMC as recited in claim 1, wherein said PMC is applied onto a multiple CPU sockets equipped computer mother board.

5. The PMC as recited in claim 4, wherein said slot has a plurality of contact points each electrically coupling to one of said PGA.

6. The PMC as recited in claim 2, wherein said PGA is electrically compatible to said CPU socket.

7. The PMC as recited in claim 4, wherein said PGA is electrically compatible to said CPU socket.
